(19) United States
(12) Patent Application Publication
(10) Pub. No.: US 2024/0196516 A1
(43) Pub. Date: Jun. 13, 2024

(54) PRINTED CIRCUIT BOARD GROUNDING

(71) Applicant: AES Global Holdings PTE Ltd., Singapore (SG)

(72) Inventors: Yihong Zhang, Shenzhen (CN); Yuk Man Shing, Kowloon (HK); Wai Chiu Or, Shenzhen (CN); Wai Man Lo, Shenzhen (CN)

(21) Appl. No.: 18/554,815

(22) PCT Filed: Apr. 15, 2021
(86) PCT No.: PCT/CN21/87563

§ 371 Date: Oct. 11, 2023

(51) Int. Cl. H05K 1/02; H05K 1/11; H05K 3/34

(52) U.S. Cl. CPC H05K 1/0215; H05K 1/115; H05K 3/3405; H05K 2201/09354; H05K 2201/1034; H05K 2201/10984; H05K 2203/0285

(57) ABSTRACT

Various configurations of a grounding element or conductive element for a printed circuit board (PCB), as well as a process for manufacturing, are disclosed. For example, a PCB can include a solder grounding element connecting a copper track to a metal substrate, where the solder grounding element is applied via ultrasonic soldering during a manufacturing process. In another example, a PCB can include a spring pin grounding element connecting a copper track to a metal substrate. In yet another example, a PCB can include an auto splice grounding element connecting a copper track to a metal substrate. In yet another example, a PCB can include a press fit pin grounding element connecting a copper track to a metal substrate. In yet another example, a PCB can include a clip pin grounding element connecting a copper track to a metal substrate.

### BACKGROUND

Multi-layer printed circuit boards (PCBs) have long been known to have problems with grounding, especially metal clad PCBs. For example, a known solution of using a screw to ground the traces to a metal substrate layer can cause multiple problems including the screw can easily damage a dielectric layer between the trace layer and the metal substrate layer. Further, a screw could damage other electrical components near the screw due to the stress of affixing the screw to the PCB. Even further, the screw may not be compact enough and could extrude the metal substrate. And lastly, installation of a screw is time consuming and inefficient production process.

### SUMMARY

In certain embodiments, a printed circuit board can include a first layer including a circuit trace, a second layer adjacent to the first layer, the second layer including a dielectric material, a third layer adjacent to the second layer opposite the first layer, the third layer including a metal substrate, and a grounding element connecting the circuit trace and the metal substrate, the grounding element including solder applied via ultrasonic soldering.

In certain embodiments, a circuit can comprise a printed circuit board including a first layer including a conductive track, a second layer including a dielectric material, a third layer including a metal substrate, the second layer located between the first layer and the third layer and a grounding element connecting the conductive track and the metal substrate, the grounding element including solder applied via ultrasonic soldering.

In certain embodiments, a method can comprise receiving a printed circuit board (PCB) having a first layer including a conductive track, a second layer including a dielectric material, a third layer including a metal substrate, the second layer located between the first layer and the third layer and applying solder via ultrasonic soldering to the PCB to create a grounding element.

### BRIEF DESCRIPTION OF THE DRAWINGS

FIG. 1 is a cross-section view of a printed circuit board with grounding, in accordance with certain embodiments of the present disclosure;

FIG. 2 is a cross-section view of a multi-layered printed circuit board with grounding, in accordance with certain embodiments of the present disclosure;

FIG. 3 is an isometric view of a printed circuit board with grounding and a cross-section view of the printed circuit board, in accordance with certain embodiments of the present disclosure;

FIG. 4 is an isometric view of a printed circuit board with grounding, a side profile view of the printed circuit board, and a cross-section view of the printed circuit board, in accordance with certain embodiments of the present disclosure;

FIG. 5 is an isometric view of a printed circuit board with grounding and an exploded view of the grounding, and a cross-section view of the printed circuit board, in accordance with certain embodiments of the present disclosure;

FIG. 6 is a front and back view of a printed circuit board with grounding and a cross-section view of the printed circuit board, in accordance with certain embodiments of the present disclosure; and

FIG. 7 is a flowchart of a method of manufacturing a printed circuit board with grounding.

### DETAILED DESCRIPTION

In the following detailed description of certain embodiments, reference is made to the accompanying drawings which form a part hereof, and in which are shown by way of illustration of example embodiments. It is also to be understood that features of the embodiments and examples herein can be combined, exchanged, or removed, other embodiments may be utilized or created, and structural changes may be made without departing from the scope of the present disclosure.

This disclosure provides solutions to the above stated problems, including providing grounding elements that do not damage the layers or other electrical components of the printed circuit board (PCB). Further, the solutions discussed herein can be integrated with the PCB and compact, taking up less of a footprint on the PCB. Further, the solutions herein can easily be incorporated into a manufacturing process.

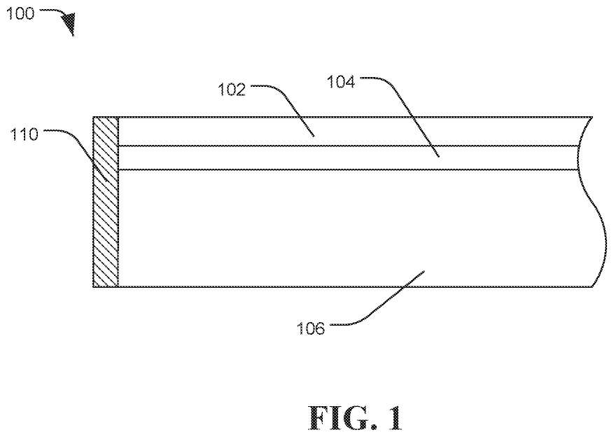

FIG. 1 shows a cross-section view of a printed circuit board with grounding, generally designated 100, in accordance with certain embodiments of the present disclosure. The printed circuit board 100 can include a top layer 102 that has a conductive element such as a track or trace for a circuit. The printed circuit board 100 can also include a middle layer 104 that has a dielectric material as an insulator. The printed circuit board 100 can further include a bottom layer 106 that can include a metal substrate. Further, the printed circuit board 100 can include a grounding element 110 that couples the conductive element of the top layer 102 to the metal substrate of the bottom layer 106.

In some embodiments, the conductive element of the top layer 102 can include copper that is formed via a manufacturing process, such as etching a copper sheet (sometimes referred to as copper clad or copper foil). The copper sheet provides the conductive part of the PCB that allows current to flow through the circuit that the conductive element establishes. Other conductive material such as stainless steel, beryllium copper, or nickel can also be used as the conductive element of the top layer 102.

In some embodiments, the dielectric material of the middle layer 104 can include any material that acts an electrical insulator by conducting minimal electricity, thus the middle layer 104 provides an insulating layer between two conducting layers, the top layer 102 and the bottom layer 106. The dielectric material provides multiple functions for PCBs. First, the dielectric materials help to isolate signals on adjacent PCB layers; second, the stability of the PCB depends on the steady impedance of the dielectric material. A dielectric material can be chosen based on its thermal properties, electrical properties, chemical properties, and mechanical properties. The thermal properties can include glass transition temperature, decomposition temperature, coefficient of thermal expansion, thermal conductivity, or any combination thereof. The electrical properties can include the dielectric constant, relative permittivity, dielectric loss tangent, dissipation factor, volume resistivity, surface resistivity, electrical strength, or any combination thereof. The chemical properties can include flammability specifications, moisture absorption, methylene chloride resistance, or any combination thereof. The mechanical properties can include peel strength, flexural strength, tensile modulus, density, time to delamination, or any combination thereof.

In some embodiments, the metal substrate of the bottom layer 106 can include a metal or metal alloy. For example, the metal substrate may include aluminum or copper, or in some cases brass, stainless steel, or a steel alloy. The bottom layer 106 can provide a very high heat dissipation compared to a PCB that does not have a metal substrate layer; the increased heat dissipation can keep heat generating components cooler and result in increased performance and life of the components or PCB. The increased heat dissipation of the metal substrate can be useful in a number of applications such as power conversions circuits, power supply circuits, light emitting diode (LED) circuits, photovoltaic circuits, telecommunication circuits, and automotive electronics, as well as others. A PCB with the metal substrate of the bottom layer 106 may be referred to as a metal core PCB, thermal PCB, or metal backed PCB.

In some embodiments, the grounding element 110 can include a metal or metal alloy that couples the conductive element of the top layer 102 to the metal substrate of the bottom layer 106. For example, the grounding element 110 may include copper or a metal alloy, such as a flux-free solder. The grounding element 110 can be created in a PCB manufacturing process or application process when a circuit is designed onto a PCB. The grounding element 110 can be soldered to the PCB using ultrasonic soldering.

Ultrasonic soldering is a soldering process that uses ultrasonic energy to eliminate the need for chemical flux. Residues left behind from the flux may be harmful to the circuit and can cause corrosion that can shorten a useful life of a circuit. In place of flux, ultrasonic soldering uses acoustic energy to disrupt oxides that form on molten solder and base metal surfaces during the joining process. Ultrasonic soldering can be implemented using ultrasonically coupled solder iron devices or ultrasonically coupled solder baths.

The grounding element 110 can be applied on an outer edge or on a through-hole of a PCB during manufacture of the PCB itself, or could be applied during a later circuit configuration process for a non-etched PCB (e.g., copper clad PCB). Applying the grounding element 110 via ultrasonic soldering allows minimal to no damage to occur to the dielectric layer, surrounding components, or the circuit traces. Further, the grounding element can be connected to the metal substrate no matter what metal or metal alloy material it is. Further, the ultrasonic soldering process can easily be integrated into a manufacturing process. Even further, ultrasonic solder can create the grounding element 110 to be no larger than is necessary, thus the grounding element 110 can be compact and require less cost and material than another solution such as the grounding screw discussed above.

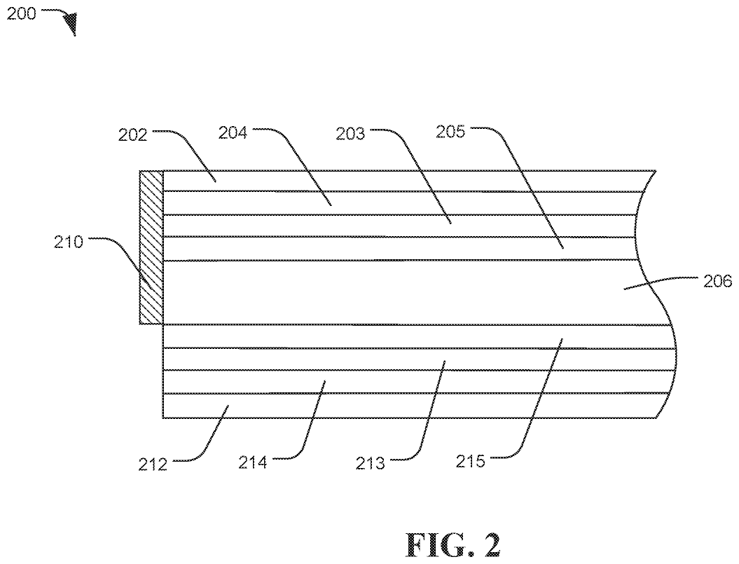

FIG. 2 shows a cross-section view of a multi-layered printed circuit board with grounding, generally designated 200, in accordance with certain embodiments of the present disclosure. The printed circuit board 200 can include a first component layer 202 and a second component layer 203 that each have a conductive element such as a track or trace for a circuit. The printed circuit board 200 can also include a first insulator layer 204 and a second insulator layer 205 that include a dielectric material. The printed circuit board 200 can further include a metal substrate layer 206. Printed circuit board 200 may be a variation of printed circuit board 100 but with at least one more component layer.

In some embodiments, the printed circuit board 200 can include a third component layer 212 and a fourth component layer 213 that each have a conductive element such as a track or trace for a circuit. The printed circuit board 200 can also include a third insulator layer 214 and a fourth insulator layer 215 that include a dielectric material.

The printed circuit board 200 can also include a conductive element 210 that couples one or more of the component layers (such as 202, 203, 212, or 213) to each other, to the metal substrate layer 206, or any combination thereof. The conductive element 210 can include a metal or metal alloy, such as a flux-free solder. Further, the conductive element 210 can be created in a PCB manufacturing process or application process when a circuit is designed onto a PCB.

In some embodiments, the conductive element 210 can be applied to the PCB 200 using ultrasonic soldering, such as to an outer edge or a through-hole of the PCB 200. The conductive element 210 can provide a conductive coupling between the component layers, the metal substrate 206, or both. The conductive element 210 is not required to provide a connection to the metal substrate 206 and could be designed to provide a connection between two or more component layers without providing a connection to the metal substrate 206. As discussed below, any of the grounding elements and techniques discussed herein can be applied to a multi-layered PCB, such as the printed circuit board 200. Further, while a four-layer PCB is shown, such is not a requirement; printed circuit board 200 may have any combination of two or more component layers.

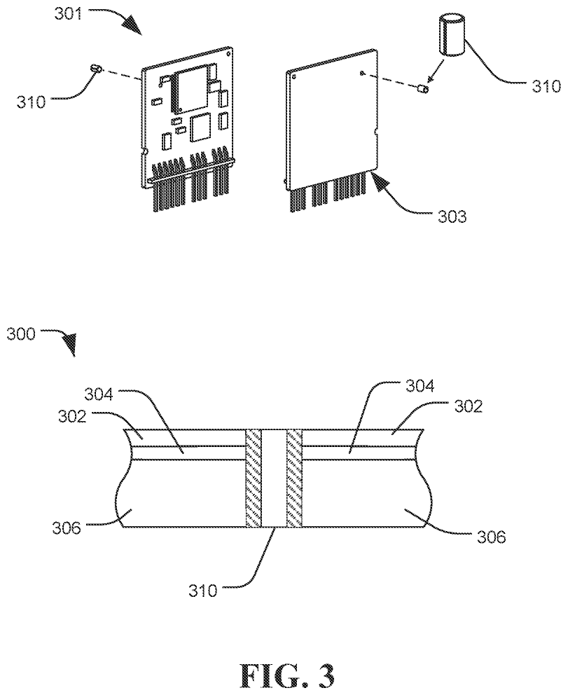

FIG. 3 shows an isometric front view 301 of a printed circuit board with grounding and a cross-section view of the printed circuit board 300, in accordance with certain embodiments of the present disclosure. FIG. 3 also shows an isometric back view 303 of the printed circuit board. The printed circuit board 300 can be the printed circuit board discussed with reference to FIG. 1 or FIG. 2, except instead of the grounding element 110 or conductive element 210 applied via ultrasonic soldering, the printed circuit board 300 can have a spring pin grounding element 310.

The printed circuit board 300 can include a top layer 302 that has a conductive element such as a track or trace for a circuit, a middle layer 304 that has a dielectric material, and a bottom layer 306 that can include a metal substrate. The grounding element 310 can connect the conductive element of the top layer 302 to the metal substrate of the bottom layer 306.

A spring pin 310 can be designed to fit within a through-hole of a PCB such that the outer edges of the spring pin 310 make an electrical connection with the top layer 302 and the bottom layer 306 to provide a ground circuit. The design of the spring pin 310 can be such that it exerts a force in a radial direction to keep itself securely within the corresponding through-hole without damaging the middle layer 304 or the PCB. Further, the spring pin 310 may be flush or recessed into each side of the PCB such that it does not extend beyond (e.g., external to) the top layer 302 or the bottom layer 306.

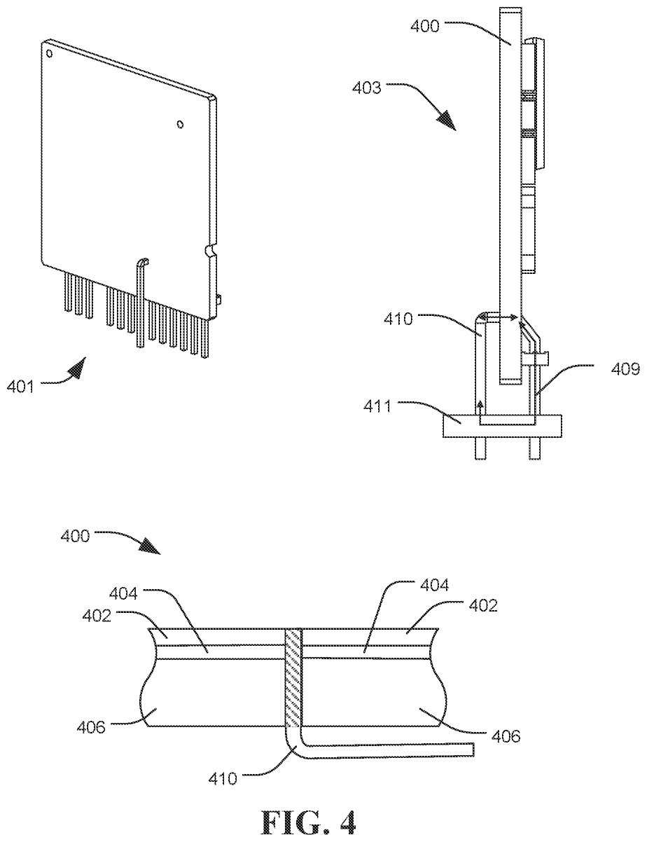

FIG. 4 shows an isometric view 401 of a printed circuit board with grounding, a side profile view 403 of the printed circuit board, and a cross-section view of the printed circuit board 400, in accordance with certain embodiments of the present disclosure. The printed circuit board 400 can be the printed circuit board discussed with reference to FIG. 1 or FIG. 2, except instead of the grounding element 110 or conductive element 210 applied via ultrasonic soldering, the printed circuit board 400 can have an auto splice grounding element 410.

The printed circuit board 400 can include a top layer 402 that has a conductive element such as a track or trace for a circuit, a middle layer 404 that has a dielectric material, and a bottom layer 406 that can include a metal substrate. The grounding element 410 can connect the conductive element of the top layer 402 to the metal substrate of the bottom layer 406.

An auto splice 410 can be designed to fit within a through-hole of a PCB such that the outer edges of the auto splice 410 make an electrical connection with the top layer 402 and the bottom layer 406 to provide a ground circuit. The design of the auto splice 410 can be such that it is a wide enough width (e.g. diameter) to keep itself securely within the corresponding through-hole without damaging the middle layer 404 or the PCB. Further, the auto splice 410 may extend from the through-hole of the PCB 400 to a through-hole of another PCB 411, such as a motherboard of a computer or other electrical system.

In some embodiments, the PCB 400 may include a grounding element 409 from the metal substrate to the other PCB 411. The grounding element 409 may be in addition to the grounding element 410 or instead of the grounding element 410.

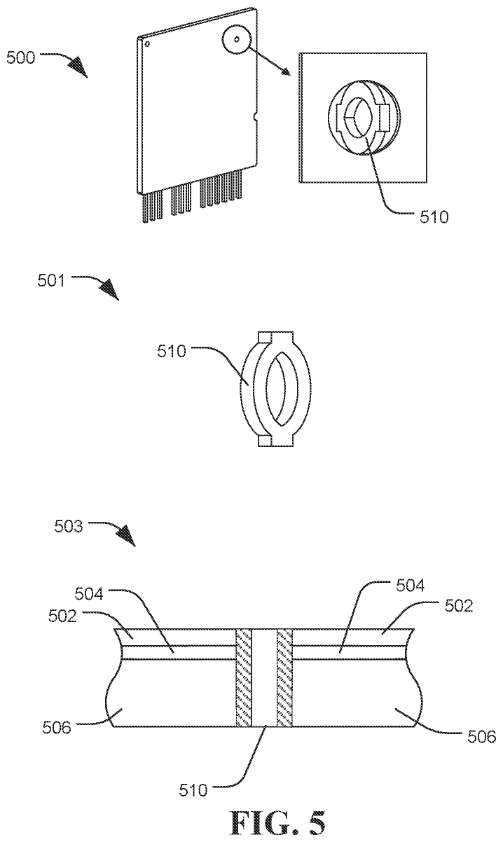

FIG. 5 shows an isometric view 500 of a printed circuit board with grounding 510 and an exploded view 501 of the grounding 510, and a cross-section view 503 of the printed circuit board 500, in accordance with certain embodiments of the present disclosure. The printed circuit board 500 can be the printed circuit board discussed with reference to FIG. 1 or FIG. 2, except instead of the grounding element 110 or conductive element 210 applied via ultrasonic soldering, the printed circuit board 500 can have a press fit grounding element 510.

The printed circuit board 500 can include a top layer 502 that has a conductive element such as a track or trace for a circuit, a middle layer 504 that has a dielectric material, and a bottom layer 506 that can include a metal substrate. The grounding element 510 can connect the conductive element of the top layer 502 to the metal substrate of the bottom layer 506.

A press fit pin 510 can be designed to fit within a through-hole of a PCB such that the outer edges of the press fit pin 510 make an electrical connection with the top layer 502 and the bottom layer 506 to provide a ground circuit. The design of the press fit pin 510 can be such that it exerts a force in an outward direction to keep itself securely within the corresponding through-hole without damaging the middle layer 504 or the PCB. Further, the press fit pin 510 may be flush or recessed into each side of the PCB such that it does not extend beyond (e.g., external to) the top layer 502 or the bottom layer 506.

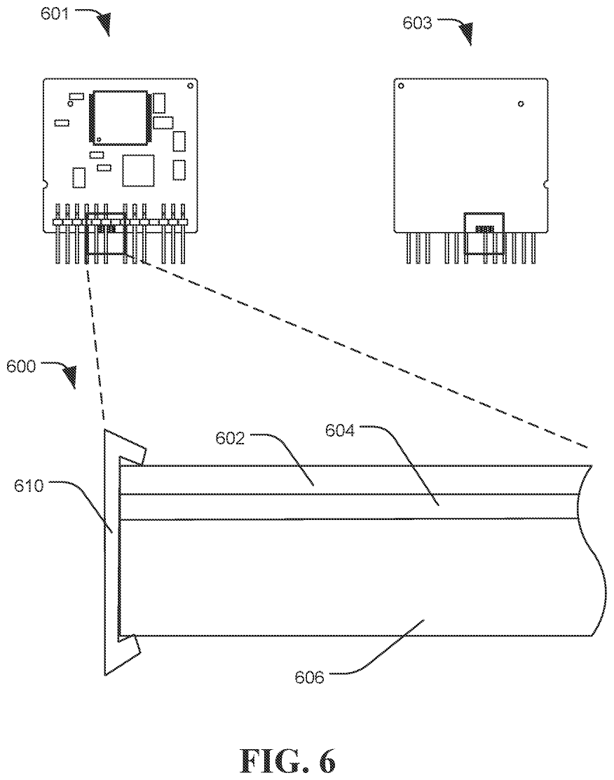

FIG. 6 shows a front view 601 and back view 603 of a printed circuit board with grounding and a cross-section view of the printed circuit board 600, in accordance with certain embodiments of the present disclosure. The printed circuit board 600 can be the printed circuit board discussed with reference to FIG. 1 or FIG. 2, except instead of the grounding element 110 or conductive element 210 applied via ultrasonic soldering, the printed circuit board 600 can have a clip grounding element 610.

The printed circuit board 600 can include a top layer 602 that has a conductive element such as a track or trace for a circuit, a middle layer 604 that has a dielectric material, and a bottom layer 606 that can include a metal substrate. The clip grounding element 610 can connect the conductive element of the top layer 602 to the metal substrate of the bottom layer 606.

The clip grounding element 610 can be formed in such a manner that the clip 610 can be securely fastened to an outer edge of the PCB 600 through the force the clip exerts itself. The clip 610 can be a conductive material that acts as a clamp to secure to the PCB and provide an electrical connection between conductive element of the top layer 602 and the metal substrate of the bottom layer 606.

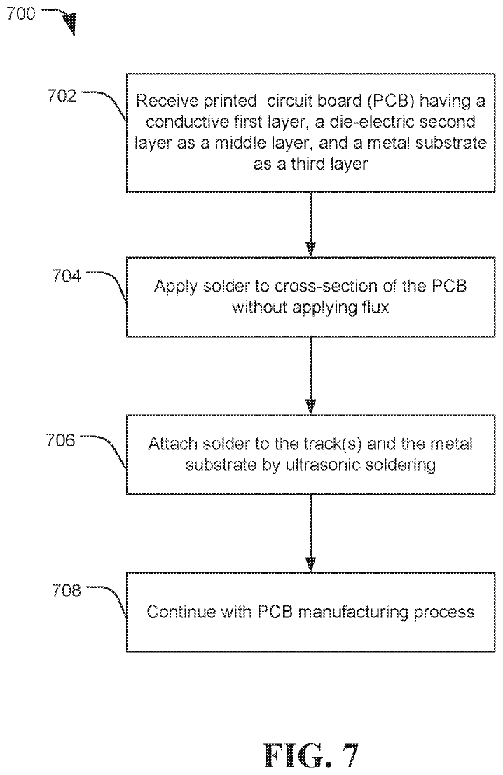

FIG. 7 shows a flowchart of a method of manufacturing a printed circuit board with grounding, generally designated 700. The process 700 can be applied during or after a PCB manufacturing process. For example, the process 700 can be applied during a manufacturing process at a PCB fabrication facility or can be applied by a PCB customer of a clad PCB where the customer can create the conductive tracks or traces from the top layer of the PCB (e.g., the copper of a copper clad).

Once a PCB has conductive tracks on a top layer, or at least the conductive traces are mapped out where they will be, the process 700 can start by receiving the PCB, at 702. One or more elements, such as grounding element 110 or conductive element 210, can be created at a specific area(s) of the PCB by applying a flux-less solder to a cross section (e.g., outer edge or through-hole) of the PCB, at 704, and then attaching the solder to the conductive element and the metal substrate via ultrasonic soldering, at 706. The PCB may then continue with a manufacturing process, at 708.

The above designs and processes can be particularly useful for a metal backed PCB or similar PCBs. In some examples, a printed circuit board can comprise a first layer including a circuit trace; a second layer adjacent to the first layer, the second layer including a dielectric material; a third layer adjacent to the second layer opposite the first layer, the third layer including a metal substrate; and a grounding element connecting the circuit trace and the metal substrate, the grounding element including solder applied via ultrasonic soldering. The solder can be applied without use of any flux material. The metal substrate can be aluminum. The metal substrate can be copper. The PCB may have an electrical surface mounted component connected to the circuit trace. The circuit trace can be copper. The solder can be applied on an outer edge of the PCB. The solder can be applied within a through hole of the PCB.

In further examples, a circuit can comprise a printed circuit board including a first layer including a conductive track, a second layer including a dielectric material, a third layer including a metal substrate, where the second layer is located between the first layer and the third layer, and a grounding element connects the conductive track and the metal substrate, the grounding element including solder applied via ultrasonic soldering. The solder can be applied without use of any flux material. The metal substrate can be copper or aluminum. An electrical surface mounted component can be connected to the conductive track. The conductive track can be copper. The solder can be applied on an outer edge or within a through hole of the PCB.

The illustrations of the embodiments described herein are intended to provide a general understanding of the structure of the various embodiments. The illustrations are not intended to serve as a complete description of all of the elements and features of apparatus and systems that utilize the structures or methods described herein. Many other embodiments may be apparent to those of skill in the art upon reviewing the disclosure. Other embodiments may be utilized and derived from the disclosure, such that structural and logical substitutions and changes may be made without departing from the scope of the disclosure. Moreover, although specific embodiments have been illustrated and described herein, it should be appreciated that any subsequent arrangement designed to achieve the same or similar purpose may be substituted for the specific embodiments shown.

This disclosure is intended to cover any and all subsequent adaptations or variations of various embodiments. Combinations of the above embodiments can be made, and other embodiments not specifically described herein will be apparent to those of skill in the art upon reviewing the description. Additionally, the illustrations are merely representational and may not be drawn to scale. Certain proportions within the illustrations may be exaggerated, while other proportions may be reduced. Accordingly, the disclosure and the figures are to be regarded as illustrative and not restrictive.

1. A printed circuit board comprising:
a first layer including a first circuit trace;
a second layer adjacent to the first layer, the second layer including a dielectric material;
a third layer adjacent to the second layer opposite the first layer, the third layer including a metal substrate; and
a grounding element connecting the first circuit trace and the metal substrate, the grounding element including solder applied via ultrasonic soldering.

2. The printed circuit board of claim 1 further comprising:
a fourth layer including a second circuit trace;
a fifth layer including a dielectric material; and
the grounding element connecting the second circuit trace and the metal substrate.

3. The printed circuit board of claim 1 further comprising the metal substrate is aluminum.

4. The printed circuit board of claim 1 further comprising the metal substrate is copper.

5. The printed circuit board of claim 1 further comprising an electrical surface mounted component connected to the first circuit trace.

6. The printed circuit board of claim 1 further comprising the first circuit trace is copper.

7. The printed circuit board of claim 1 further comprising the solder is applied on an outer edge of the printed circuit board.

8. The printed circuit board of claim 1 further comprising the solder is applied within a through hole of the printed circuit board.

9. A circuit comprising:
a printed circuit board including:
a first layer including a first track;
a second layer including a dielectric material;
a third layer including a metal substrate;
the second layer located between the first layer and the third layer; and
a conductive element connecting the first track and the metal substrate, the conductive element including solder applied via ultrasonic soldering.

10. The circuit of claim 9 further comprising:
a fourth layer including a second track;
a fifth layer including a dielectric material; and
the conductive element connecting the second track and the metal substrate.

11. The circuit of claim 9 further comprising the metal substrate is copper.

12. The circuit of claim 9 further comprising the metal substrate is aluminum.

13. The circuit of claim 12 further comprising an electrical surface mounted component connected to the conductive track.

14. The circuit of claim 12 further comprising the conductive track is copper.

15. The circuit of claim 14 further comprising the solder is applied on an outer edge of the printed circuit board.

16. The circuit of claim 14 further comprising the solder is applied within a through hole of the printed circuit board.

17. A method comprising:
receiving a printed circuit board (PCB) having a first layer including a conductive track, a second layer including a dielectric material, a third layer including a metal substrate, the second layer located between the first layer and the third layer; and
applying solder via ultrasonic soldering to the PCB to create a grounding element.

18. The method of claim 17 further comprising the solder is applied without use of a flux material.

19. The method of claim 17 further comprising the conductive track includes copper and the metal substrate includes aluminum.

20. The method of claim 19 further comprising applying the solder on an outer edge of the PCB.
